(19) United States
(12) Patent Application Publication
(10) Pub. No.: US 2012/0313008 A1
(43) Pub. Date: Dec. 13, 2012

(54) FLUORESCENT DETECTOR

(75) Inventors: Sung-Ho JO, Changwon-city (KR); Seong-Kook KIM, Changwon-city (KR); Tae-Gon KIM, Changwon-city (KR)

(73) Assignee: SAMSUNG TECHWIN CO., LTD., Changwon-city (KR)

(21) Appl. No.: 13/492,035

(22) Filed: Jun. 8, 2012

(30) Foreign Application Priority Data
Jun. 9, 2011 (KR) 10-2011-0055819

(51) Int. Cl. G01J 1/58; H01L 31/0232

(52) U.S. Cl. 250/458.1; 250/216

(57) ABSTRACT

A fluorescence detector for detecting fluorescence emitted from at least one sample contained in at least one sample unit, the fluorescence detector including at least one irradiating module which irradiates an excitation light to the sample; a fluorescence selecting unit which selectively transmits fluorescence emitted from the sample; a light-receiving unit which detects the fluorescence; and a telecentric lens positioned between the fluorescence selecting unit and the light-receiving unit, wherein each of the at least one irradiating module comprises: at least one light source which emits a light; an excitation light selecting unit which converts the light emitted from the at least one light source into the excitation light; and a beamsplitter which controls the excitation light to travel to the sample, and transmits the fluorescence emitted from the sample.

### CROSS-REFERENCE TO RELATED PATENT APPLICATION

This application claims priority from Korean Patent Application No. 10-2011-0055819, filed on Jun. 9, 2011, in the Korean Intellectual Property Office, the disclosure of which is incorporated herein in its entirety by reference.

### BACKGROUND

1. Field

The present invention relates to a fluorescence detector.

2. Description of the Related Art

In amplifying nucleic acid, devices to check whether nucleic acid amplification is effectively performed after every cycle are required. In general, these devices detect fluorescence emitted from a sample to determine whether the nucleic acid amplification is effectively performed. That is, when a complementary probe is attached to a nucleic acid, and then, an excitation light is applied thereto, the excited probe emits fluorescence, and the devices detect the fluorescence.

However, the devices to detect fluorescence according to the related art are huge in size and heavy in weight, and when fluorescence or an excitation light passes through an optical system, a wavelength shift occurs such that interference occurs between several lights, and thus, a detection accuracy deteriorates.

### SUMMARY

One or more exemplary embodiments provide a fluorescence detector that detects fluorescence from a sample.

According to an aspect of an exemplary embodiment, there is provided a fluorescence detector for detecting fluorescence emitted from at least one sample contained in at least one sample unit, the fluorescence detector including at least one irradiating module which irradiates an excitation light to the sample; a fluorescence selecting unit which selectively transmits fluorescence emitted from the sample; a light-receiving unit which detects the fluorescence; and a telecentric lens positioned between the fluorescence selecting unit and the light-receiving unit, wherein each of the at least one irradiating module comprises: at least one light source which emits a light; an excitation light selecting unit which converts the light emitted from the at least one light source into the excitation light; and a beamsplitter which controls the excitation light to travel to the sample, and transmits the fluorescence emitted from the sample.

The irradiating module may further include a collimation lens which is disposed between the at least one light source and the excitation light selecting unit, and collimates the light emitted from the at least one light source.

The irradiating module may be movable in a first direction.

The number of the at least one irradiating module is two or more, and the two or more irradiating modules are disposed in parallel along one direction, and wherein respective excitation light selecting units of the two or more irradiating modules convert respective lights emitted from respective at least one light source into respective excitation lights having different wavelengths.

The at least one light source may include at least one light-emitting diode (LED) lighting.

The number of the at least LED lighting may be equal to the number of the at least one sample unit.

The fluorescence selecting unit may include an emission filter.

The emission filter may be formed of a plurality of the emission filters, and the plurality of emission filters may be changeable with respect to one another.

The light-receiving unit may include a charge-coupled device (CCD) camera.

The beamsplitter may include a dichroic filter.

An incident angle of the excitation light that is incident on the dichroic filter may be between 40 degrees and 50 degrees.

The excitation light selecting unit may include an excitation filter.

An incident angle of light from the irradiating module that is incident on the excitation filter may be between −5 degrees and 5 degrees.

The excitation light is a selected wavelength light.

The irradiating module may further include a wave guide which is disposed between the at least one light source and the excitation light selecting unit and divides the light emitted from the at least one light source into a plurality of lights that are parallel to one another.

The wave guide may be a glass wave guide which is integrally formed of a glass material.

The wave guide may include a plurality of optical fibers, and side ends of the plurality of optical fibers toward the at least one light source contact one another, and side ends of the plurality of optical fibers toward the excitation light selecting unit are separate from one another.

According to an aspect of another exemplary embodiment, there is provided a fluorescence detector for detecting fluorescence emitted from at least one sample contained in at least one sample unit, the fluorescence detector including an irradiating module which irradiates an excitation light to the sample; a fluorescence selecting unit which selectively transmits fluorescence emitted from the sample; a light-receiving unit which detects the fluorescence; and a telecentric lens positioned between the fluorescence selecting unit and the light-receiving unit, wherein the irradiating module includes: a light source comprising at least one laser diode which emits a light; and a beamsplitter which controls the light emitted from the at least one laser diode of the light source to travel to the sample, and transmits the fluorescence emitted from the sample.

A wavelength of the light emitted from the at least one laser diode may be materially the same as a wavelength of light capable of exciting a fluorescent material comprised in the sample.

The irradiating module may further include an excitation light selecting unit which is disposed between the light source and the beamsplitter and converts the light emitted from the light source into the excitation light.

### BRIEF DESCRIPTION OF THE DRAWINGS

The above and other aspects will become more apparent by describing in detail exemplary embodiments thereof with reference to the attached drawings, in which:

FIG. 1 is a perspective view of a fluorescence detector according to an exemplary embodiment;

FIG. 2 is a cross-sectional view of the fluorescence detector of FIG. 1 when excitation light is irradiated to a sample, according to an exemplary embodiment;

FIG. 3 is a cross-sectional view of the fluorescence detector of FIG. 1 when fluorescence from the sample is detected, according to an exemplary embodiment;

FIG. 4 is a perspective view of an irradiating module of FIG. 1 according to an exemplary embodiment;

FIG. 5 is a cross-sectional view of the irradiating module of FIG. 4 according to an exemplary embodiment;

FIG. 6 illustrates processes in which the irradiating module formed of a plurality of irradiating modules of FIG. 4 irradiates excitation light to a sample, according to an exemplary embodiment;

FIG. 7 is a perspective view illustrating another example of a fluorescence selecting unit in the fluorescence detector according to an exemplary embodiment;

FIG. 8 illustrates another type of irradiating module according to an exemplary embodiment;

FIG. 9 illustrates another irradiating module including a wave guide formed of a plurality of optical fibers according to an exemplary embodiment; and

FIG. 10 illustrates another irradiating module including a light source having a plurality of laser diodes according to an exemplary embodiment.

### DETAILED DESCRIPTION OF EXEMPLARY EMBODIMENTS

Hereinafter, the inventive concept will be described in detail by explaining exemplary embodiments with reference to the attached drawings.

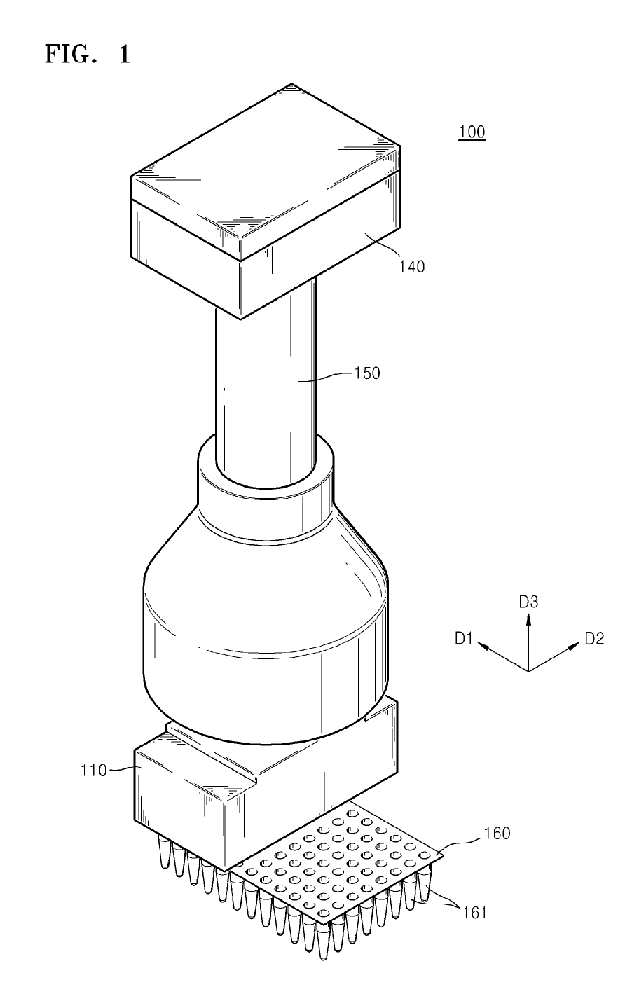

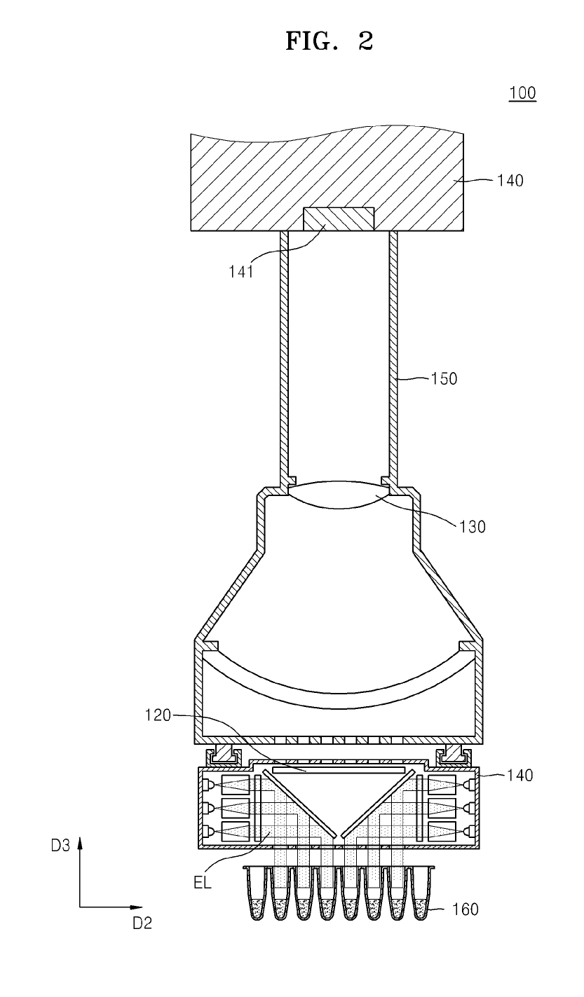

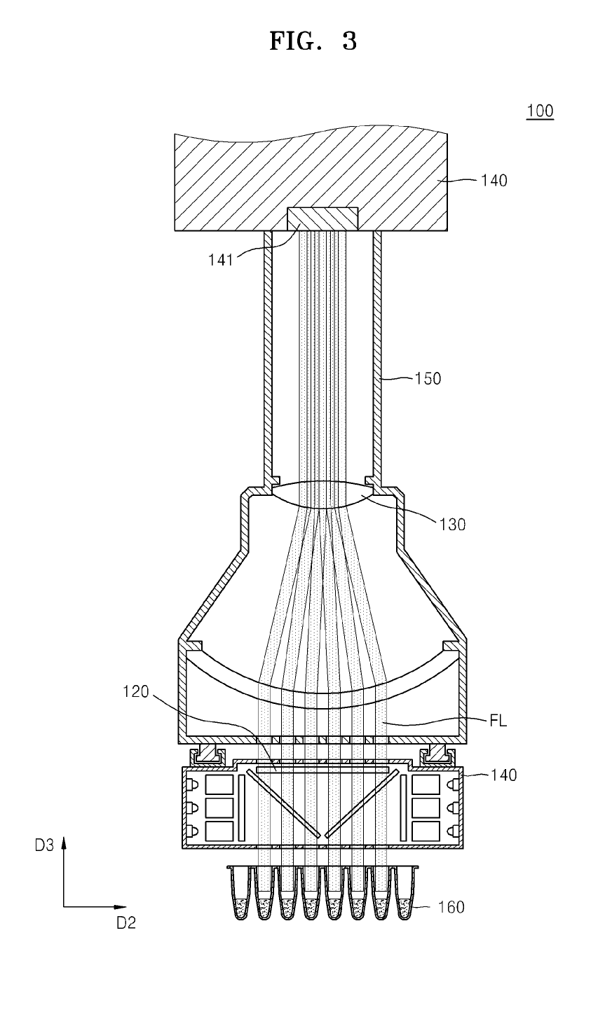

FIG. 1 is a perspective view of a fluorescence detector 100 according to an exemplary embodiment. FIG. 2 is a cross-sectional view of the fluorescence detector 100 of FIG. 1 when an excitation light EL is irradiated to a sample T (refer to FIG. 2). FIG. 3 is a cross-sectional view of the fluorescence detector 100 of FIG. 1 when fluorescence from a sample T (refer to FIG. 3) is detected.

The fluorescence detector 100 may include an irradiating module 110, a fluorescence selecting unit 120, a telecentric lens 130, and a light-receiving unit 140, and may further include a housing 150 that accommodates at least some of the aforementioned elements.

The fluorescence detector 100 is a device which determines an existence or an amount of a target included in the sample T by exciting the target and then detecting the fluorescence (FL) emitted from the target.

In the present embodiment, the target included in the sample T is a nucleic acid, and a probe complementary to a particular nucleic acid is attached to the particular nucleic acid, and then the excitation light EL is irradiated thereto so as to excite the probe. Afterward, by detecting the fluorescence emitted from the excited probe, it is possible to determine an existence or an amount of the probe, and based on the determination, an existence or an amount of the particular nucleic acid may be determined. This procedure will be described below in detail.

In general, the fluorescence detector 100 may be used in a polymerase chain reaction (PCR). That is, the fluorescence detector 100 may monitor an amplified amount of a nucleic acid after the PCR is completed at every cycle.

The sample T is included in a sample group 160. The sample group 160 includes one or more sample units 161, and the sample group 160 of FIG. 1 includes 96 sample units 161 (i.e., 12 columns in a first direction D1 and 8 rows in a second direction D2). In the present embodiment, the fluorescence detector 100 only detects the sample T positioned in a region corresponding to eight columns in the first direction D1 and six rows in the second direction D2.

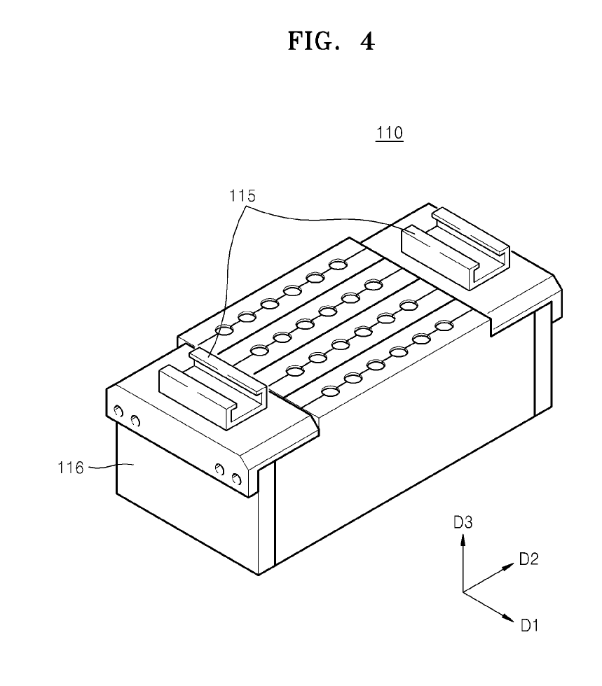

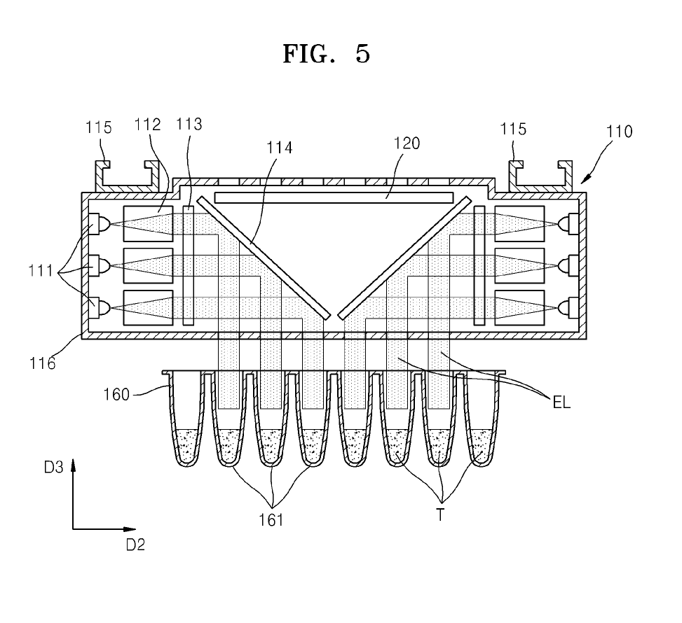

FIG. 4 is a perspective view of the irradiating module 110 of FIG. 1, and FIG. 5 is a cross-sectional view of the irradiating module 110 of FIG. 4.

The irradiating module 110 irradiates the excitation light EL to the sample T, and includes a light source 111, a collimation lens 112, an excitation light selecting unit 113, and a beamsplitter 114.

The irradiating module 110 may be positioned above the sample group 160 and may move along a first direction D1. Also, the irradiating module 110 may include a plurality of the irradiating modules 110, and the plurality of irradiating modules 110 may be disposed in parallel to each other along one direction (in the present embodiment, they are disposed along the first direction D0. Here, each of the irradiating modules 110 may be regarded as a channel, and the irradiating modules 110 of the channels may be used to detect different types of nucleic acids. To do so, the irradiating modules 110 of the channels may emit lights having different wavelengths so as to excite probes to be attached to the different types of nucleic acids, and to do so, the irradiating modules 110 of the channels may include different types of light sources 111 or different types of excitation light selecting units 113. In the irradiating module 110 of FIG. 4, six rows that are horizontally arrayed correspond to one channel, and in this regard, the irradiating module 110 is formed of four channels so that four different types of fluorescence may be detected with respect to the sample T included in one sample unit 161.

The light source 111 includes one or more light-emitting diode (LED) lightings. In order to observe various samples T, the LED lightings may include various types of LEDs according to wavelengths required to excite the various samples T. In the present embodiment, the LED lightings may have wavelengths of 470 nm, 520 nm, 590 nm, 640 nm, or the like but one or more embodiments are not limited thereto. Alighting with an appropriate wavelength may be used according to a target sample T, and the lighting is not limited to LED lighting.

The number of LED lightings included in the light source 111 may match with the number of sample units 161 to be observed. Referring to FIG. 5, in order to perform detection on the sample units 161 in six rows, the light source 111 includes six LED lightings, and three LED lightings arrayed in a single row along a third direction D3 are disposed in left and right sides, respectively.

The collimation lens 112 is positioned in a rear side of the light source 111 on an optical path, and the collimation lenses 112 are arranged to correspond to the LED lightings included in the light source 111, respectively. The collimation lens 112 collimates a travel path of light emitted from the light source 111.

The excitation light selecting unit 113 may be positioned in a rear side of the collimation lens 112 on the optical path and may include an excitation filter. The excitation light selecting unit 113 receives the light emitted from the collimation lens 112 and then outputs the excitation light EL that has a particular wavelength so as to excite the sample T. In more detail, the light emitted from the LED lighting has a Gaussian distribution with respect to a wavelength, and in this regard, when the light passes through the excitation filter, other portions of the light except for a portion of the light with a particular band wavelength do not pass through the excitation filter, and only the portion of the light with the particular band wavelength passes through the excitation filter.

In the present embodiment, the excitation light selecting unit 113 has one excitation filter with respect to lights emitted from the three LED lightings, but one or more embodiments are not limited thereto and the excitation light selecting unit 113 may include excitation filters that correspond to LED lightings, respectively.

The light that collimates after passing through the collimation lens 112 is incident on the excitation filter, and in this regard, an incident angle of the light with respect to the excitation filter may be between about −5 degrees and about 5 degrees, and it is optimal when the incident angle is 0 degrees. With the aforementioned range of incident angle, a wavelength shift that may occur when the light passes through the excitation filter may be effectively prevented and a wavelength of the light passing through the excitation filter may be accurately controlled.

The beamsplitter 114 is positioned in a rear side of the excitation light selecting unit 113 on the optical path, and functions to reflect the excitation light EL and to transmit fluorescence. The beamsplitter 114 may include a dichroic filter. The dichroic filter has a property of transmitting a light having a particular wavelength and of reflecting lights having the rest of the wavelengths. The dichroic filter used in the present embodiment may transmit a light having a wavelength of fluorescence emitted from the sample T and may reflect lights having the rest of the wavelengths including a wavelength of the excitation light EL.

The excitation light EL emitted from the excitation light selecting unit 113 is incident on the beamsplitter 114. Here, an incident angle of the excitation light EL with respect to the beamsplitter 114 may be between about 40 degrees and about 50 degrees, and it is optimal when the incident angle is 45 degrees. When a value of the incident angle is limited to the aforementioned range, a wavelength shift that may occur when a light is reflected by the dichroic filter may be effectively reduced, so that the wavelengths may be accurately controlled and detection of the fluorescence may be further accurately performed.

Moving units 115 are formed on a top surface of an irradiating module cover 116 and move the irradiating module 110 in the first direction D1. In the present embodiment, the first direction D1 is parallel to a direction in which 12 sample units 161 are arrayed in a single row in the sample group 160. However, one or more embodiments are not limited thereto and thus the first direction D1 may be changed according to a designer's objective.

The moving unit 115 includes a rail arranged on the irradiating module 110 and a rail arranged at a lower part of the housing 150. Both the rails engage with each other and are movable relatively to the other. The movement of the rails may be driven by a motor (not shown). However, one or more embodiments are not limited thereto, and thus, a way that the moving units 115 move the irradiating module 110 in one direction may be other ways for moving objects according to the related art.

A fluorescence selecting unit 120 is a portion to which the fluorescence emitted from the sample T is incident after passing through the beamsplitter 114. The fluorescence selecting unit 120 may include an emission filter.

The fluorescence selecting unit 120 transmits only a light having a wavelength of the fluorescence among incident lights. That is, a light emitted from the LED lightings is highly intensive, compared to the fluorescence emitted from the sample T. Thus, if the light from the LED lighting is directly incident to the light-receiving unit 140 for detection, a detection accuracy result considerably deteriorates. The fluorescence selecting unit 120 may be arranged to prevent the deterioration and may be formed in a path on which a light emitted from the sample T travels to the light-receiving unit 140. In the present embodiment, the fluorescence selecting unit 120 is formed in the irradiating module 110. However, one or more embodiments are not limited thereto, and thus, the fluorescence selecting unit 120 may be positioned in the housing 150.

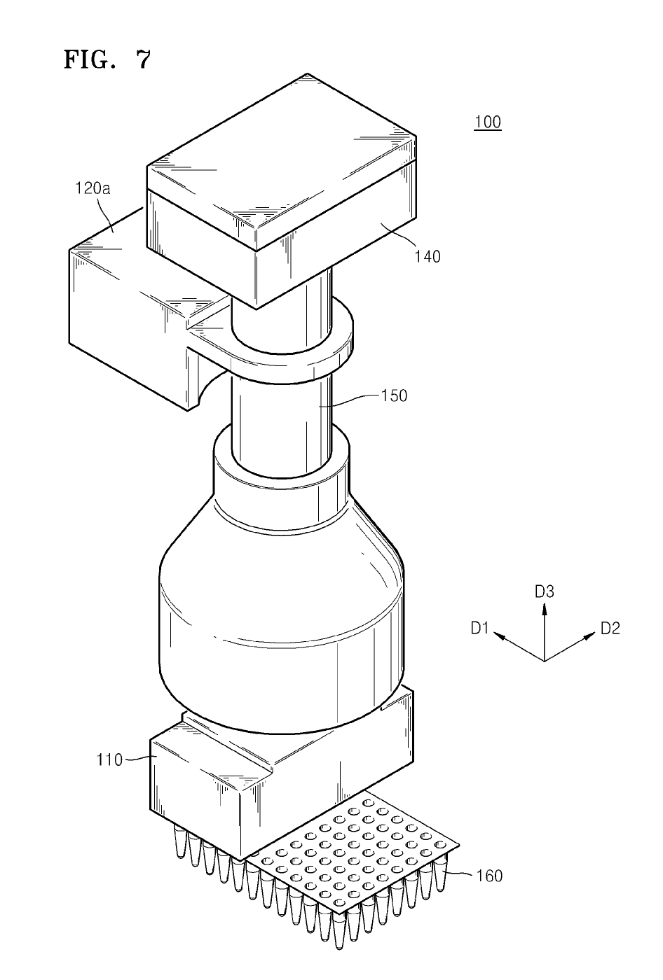

FIG. 7 is a perspective view illustrating another example of the fluorescence selecting unit 120 in the fluorescence detector 100.

Referring to the modified example of FIG. 7, the fluorescence selecting unit 120 may include a plurality of emission filters and may also include a filter changing unit 120a to change the emission filters according to situations.

In order to transmit fluorescence lights having different wavelengths which occur via a plurality of channels of the irradiating module 110, the change of the emission filters is performed by the filter changing unit 120a.

For example, when an excitation light EL having a first excitation light wavelength is irradiated to the sample T via a first channel, if it is assumed that fluorescence having a first fluorescence wavelength is emitted from the sample T, a first emission filter for transmitting the fluorescence having the first fluorescence wavelength is mounted by the filter changing unit 120a. Afterward, when an excitation light EL having a second excitation light wavelength is irradiated to the sample T via a second channel, if fluorescence having a second fluorescence wavelength is emitted from the sample T, a second emission filter that corresponds to the fluorescence having the second fluorescence wavelength is mounted by the filter changing unit 120a.

Thus, in correspondence to fluorescence lights having different wavelengths which occur via the channels of the irradiating module 110, the filter changing unit 120a selectively mounts the emission filter for transmitting a corresponding fluorescence light in the fluorescence selecting unit 120. That is, by selectively choosing the emission filter that corresponds to one of the different wavelengths, the fluorescence lights having the different wavelengths may be detected.

The telecentric lens 130 is disposed on a path on which fluorescence emitted from the sample T travels to the light-receiving unit 140, so that the fluorescence passes through the fluorescence selecting unit 120 and then passes through the telecentric lens 130. The telecentric lens 130 may include various optical elements and may be formed by combining the various optical elements. In the present embodiment, the telecentric lens 130 includes only one lens but one or more embodiments are not limited thereto.

The telecentric lens 130 transmits only light with a small allowance incident angle (e.g., between about −2 degrees and about 2 degrees) from among lights that are incident on the telecentric lens 130. That is, when lights are incident on the telecentric lens 130 via various paths, only a light that is approximately parallel to a particular direction passes through the telecentric lens 130. Because the telecentric lens 130 has the small allowance incident angle, when light passes through the telecentric lens 130, a wavelength shift does not occur. Thus, it is possible to accurately control a wavelength of fluorescence, and interference between fluorescence lights of different wavelengths generated via the multiple channels does not occur. Therefore, an accurate detection result may be achieved.

The light-receiving unit 140 may detect fluorescence emitted from the sample T and may include various types of detection sensors. In the present embodiment, the light-receiving unit 140 includes a charge-coupled device (CCD) camera 141 as a sensor for detecting the fluorescence (FL).

Hereinafter, an operation process of the fluorescence detector 100 will be described.

Referring to FIGS. 2 and 3, the operation process of the fluorescence detector 100 may be divided into an excitation light EL irradiation process shown in FIG. 2, and a fluorescence detection process shown in FIG. 3.

First, as illustrated in FIGS. 2 and 5, in the excitation light EL irradiation process via the irradiating module 110, a light is emitted from the light source 111. Here, the light is emitted while being dispersed in various directions, and when the light passes through the collimation lens 112, the light is convergently emitted in a particular direction and then travels while being parallel to a second direction (D2). The light that has passed through the collimation lens 112 passes through the excitation light selecting unit 113, and at this time, a wavelength of the excitation light EL, which is required to excite a sample T that is a target, is selectively emitted. That is, when the light passes through the excitation filter included in the excitation light selecting unit 113, only a particular band wavelength is emitted from the excitation light selecting unit 113. The excitation light EL emitted therefrom is incident on the beamsplitter 114, and then the excitation light EL is reflected at the same reflection angle as an incident angle (approximately 45 degrees). The reflected excitation light EL is incident on the sample T in an opposite direction to a third direction D3, and because the excitation light EL is approximately vertically incident on the sample T, a spatial deviation of the excitation light EL which occurs in the sample T is very small. In this manner, the excitation light EL irradiated to the sample T excites the sample T, so that fluorescence is generated in and is emitted from the sample T.

Hereinafter, the fluorescence FL detection process will be described with reference to FIG. 3.

As the sample T is excited, the sample T emits fluorescence. Here, the fluorescence moves along a third direction D3 and keeps moving after passing through the dichroic filter of the beamsplitter 114. Afterward, the fluorescence passes through the fluorescence selecting unit 120 positioned in the irradiating module 110, and in this process, the excitation light EL of the light incident on the fluorescence selecting unit 120 is filtered, and only the fluorescence passes through the fluorescence selecting unit 120. Afterward, when the fluorescence passes through the telecentric lens 130, only the fluorescence of which an incident angle with respect to the telecentric lens 130 is between about −2 degrees and about 2 degrees passes through the telecentric lens 130, and after this process, the fluorescence becomes parallel, is incident on the light-receiving unit 140 disposed in a top portion, and then is detected.

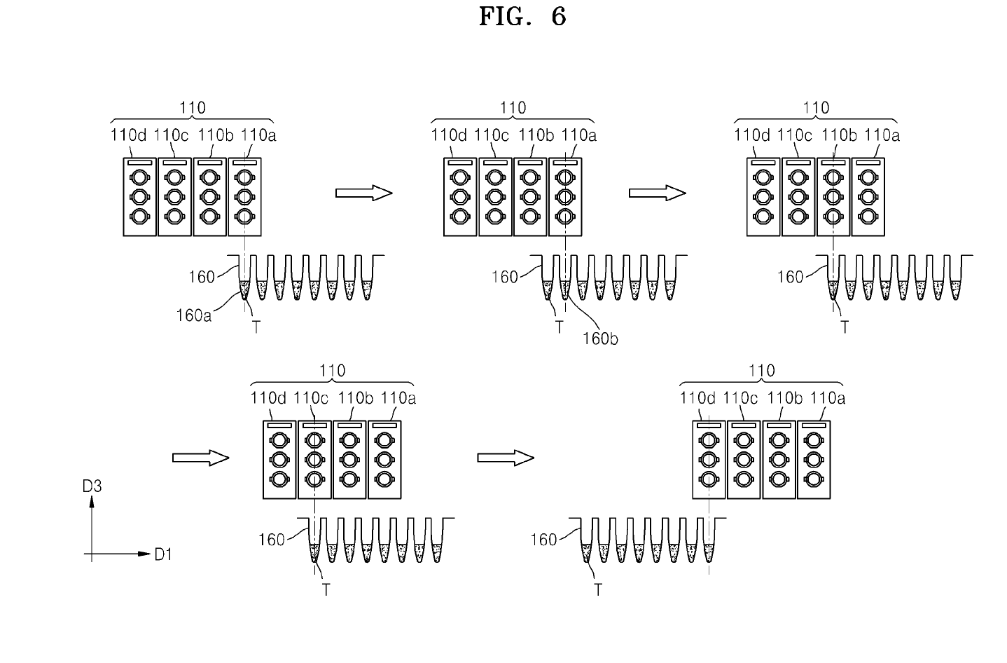

FIG. 6 illustrates processes in which the irradiating module 110 formed of a plurality of irradiating modules of FIG. 4 irradiates excitation light EL to a sample T.

The irradiating module 110 of FIG. 6 is formed of four channels (i.e., first through fourth channels) of irradiating modules 110a, 110b, 110c, and 110d, and the four channels of the irradiating modules 110a, 110b, 110c, and 110d move in a first direction (D1) and sequentially irradiate the excitation light EL to the sample T. However, the processes shown in FIG. 6 do not show all processes in which the four channels of the irradiating modules 110a, 110b, 110c, and 110d sequentially irradiate the excitation light EL to all sample units 161 of eight columns but partially exhibit the processes, and in this regard, the processes and an order of the processes are exemplary.

For example, after the first channel of the irradiating module 110a irradiates the excitation light EL to a first sample unit 160a that is first positioned in the first direction (D1), the first channel of the irradiating module 110a moves in the first direction (D1) and then irradiates the excitation light EL to a second sample unit 160b. Afterward, the second channel of the irradiating module 110b slightly moves in the first direction (D1), and irradiates the excitation light EL to the second sample unit 160b. Afterward, the four channels of the irradiating modules 110a, 110b, 110c, and 110d move in the first direction (D1) and sequentially perform the aforementioned processes.

In this regard, when the four channels of the irradiating module 110 irradiate the excitation light EL to each sample unit, an emission filter that corresponds to a wavelength of fluorescence (FL) emitted from each sample T may be changed by the filter changing unit 120a.

In the present embodiment, the irradiating module 110 includes a plurality of the light sources 111 and a plurality of the collimation lenses 112, but a structure of the irradiating module 110 may vary.

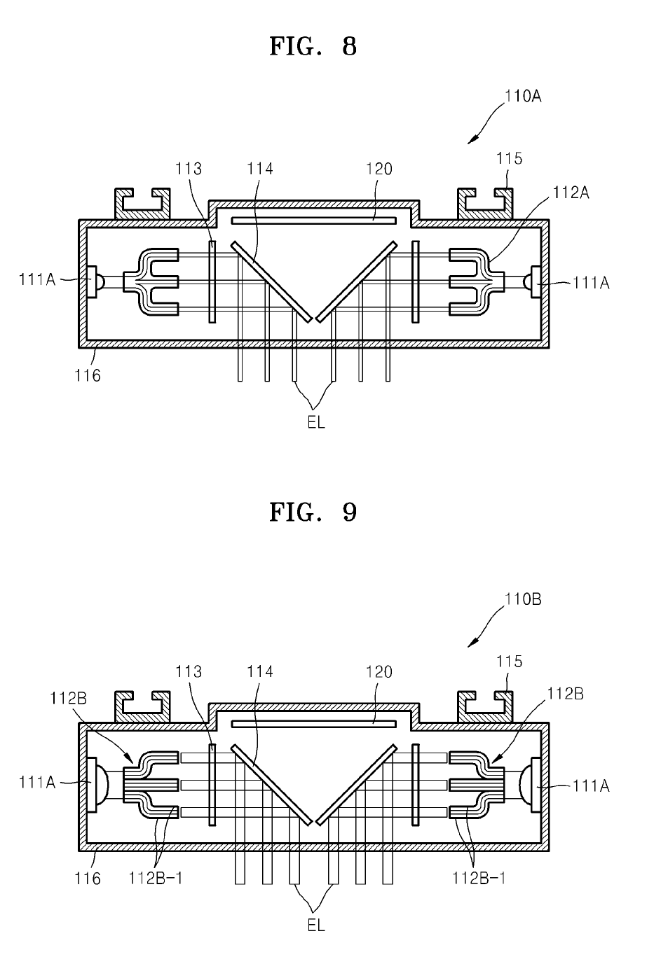

FIG. 8 is a diagram illustrating another example of irradiating module 110A.

Referring to FIG. 8, the irradiating module 110A includes a light source 111A, a wave guide 112A, an excitation light selecting unit 113, a beamsplitter 114, a fluorescence selecting unit 120, an irradiating module cover 116, and a moving unit 115. The excitation light selecting unit 113, the beamsplitter 114, the fluorescence selecting unit 120, the irradiating module cover 116, and the moving unit 115 of the irradiating module 110A of FIG. 8 are the same as those of the fluorescence detector 100 according to the previous embodiment. Thus, detailed descriptions thereof are omitted here.

The light source 111A of the irradiating module 110A of FIG. 8 may be formed of one light source, e.g., one light-emitting diode (LED).

The wave guide 112A is disposed between the light source 111A and the excitation light selecting unit 113, and divides a light from the light source 111A into a plurality of lights that are parallel to each other. The wave guide 112A may be a glass wave guide that is integrally formed of a glass material. The wave guide 112A of the irradiating module 110A of FIG. 8 has a plurality of branches toward the excitation light selecting unit 113, so that the light from the light source 111A is divided into the plurality of lights that are parallel to one another, and in this regard, the branches are parallel to one another. Thus, the light from the light source 111A enters the wave guide 112A, and is divided into the plurality of lights by moving along the wave guide 112A.

Thus, by using the irradiating module 110A of FIG. 8, an excitation light may be irradiated to a plurality of samples, although one light source is used. In particular, because the irradiating module 110A of FIG. 8 uses one light source, when the wave guide 112A is designed to divide an incident light into a plurality of lights having the same intensity, intensities of excitation lights emitted toward samples may be equal to each other. When the intensities of the excitation lights are equal to each other, relative densities of fluorescent materials included in the samples may be accurately measured because an error resulted from a deviation of the intensity of the excitation light may be effectively removed.

In addition, the wave guide 112A of the irradiating module 110A of FIG. 8 may be formed of a plurality of optical fibers.

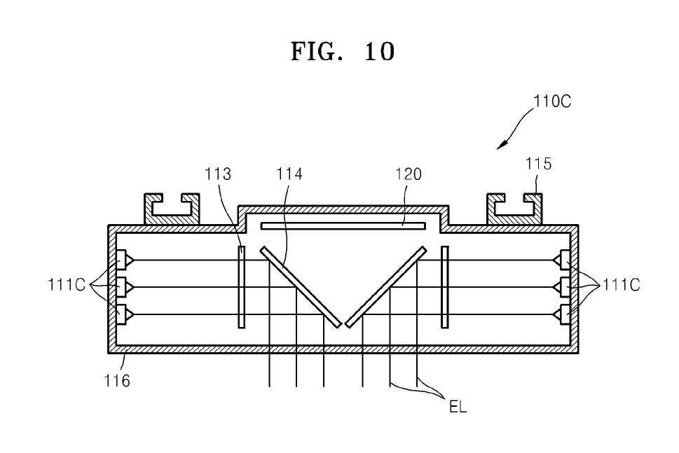

FIG. 9 illustrates another irradiating module 110B including a wave guide 112B formed of a plurality of optical fibers 112B-1.

Referring to FIG. 9, the wave guide 112B includes the plurality of optical fibers 112B-1. The plurality of optical fibers 112B-1 are combined with each other in a bunch form. In this regard, side ends of the plurality of optical fibers 112B-1 toward a light source 111A contact each other, and side ends of the plurality of optical fibers 112B-1 toward an excitation light selecting unit 113 are separate from one another. That is, the bunch of the plurality of optical fibers 112B-1 has a shape in which the plurality of optical fibers 112B-1 are separated from one another while they extend from the light source 111A toward the excitation light selecting unit 113. Thus, the wave guide 112B including the plurality of optical fibers 112B-1 divides the light emitted from the light source 111A into a plurality of lights. Therefore, without a plurality of light sources, the plurality of lights may be irradiated to samples via the excitation light selecting unit 113 and a beamsplitter 114.

Also, a light source of an irradiating module may include a laser diode.

FIG. 10 illustrates another irradiating module 110C including a light source 111C having a plurality of laser diodes.

Referring to FIG. 10, the light source 111C of the irradiating module 110C has the plurality of laser diodes. Also, the irradiating module 110C includes an excitation light selecting unit 113, a beamsplitter 114, a fluorescence selecting unit 120, an irradiating module cover 116, and a moving unit 115 that are materially the same as those of the fluorescence detector 100 according to the previous embodiment.

The plurality of laser diodes of the light source 111C are vertically disposed and irradiate a laser toward the beamsplitter 114. The laser diode emits the laser formed of light having a narrow frequency band. Because the laser diode is well known, descriptions of its structure and operational principle are omitted here. Because the laser has an excellent straight-advance characteristic and does not disperse, when the light source 111C has the plurality of laser diodes, a collimation lens is not separately required between the light source 111C and the beamsplitter 114. Thus, an increase in manufacturing costs due to an installation of the collimation lens may be effectively restricted, and the irradiating module 110C may have a simple structure. The laser diode of the light source 111C may emit the laser having materially the same frequency band as an excitation light capable of exciting a fluorescent material of a sample. The excitation light selecting unit 113 may be disposed between the plurality of laser diodes of the light source 111C and the beamsplitter 114 to block a light having another wavelength other than a wavelength corresponding to the excitation light. However, when the plurality of laser diodes of the light source 111C have materially the same frequency band as the excitation light, the excitation light selecting unit 113 may not be separately disposed between the plurality of laser diodes and the beamsplitter 114.

The one or more embodiments may provide a fluorescence detector having an excellent fluorescence detection performance.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims.

What is claimed is:

1. A fluorescence detector for detecting fluorescence emitted from at least one sample contained in at least one sample unit, the fluorescence detector comprising:
at least one irradiating module which irradiates an excitation light to the sample;
a fluorescence selecting unit which selectively transmits fluorescence emitted from the sample;
a light-receiving unit which detects the fluorescence; and
a telecentric lens positioned between the fluorescence selecting unit and the light-receiving unit,
wherein each of the at least one irradiating module comprises:
at least one light source which emits a light;
an excitation light selecting unit which converts the light emitted from the at least one light source into the excitation light; and
a beamsplitter which controls the excitation light to travel to the sample, and transmits the fluorescence emitted from the sample.

2. The fluorescence detector of claim 1, wherein the irradiating module further comprises a collimation lens which is disposed between the at least one light source and the excitation light selecting unit, and collimates the light emitted from the at least one light source.

3. The fluorescence detector of claim 1, wherein the irradiating module is movable in a first direction.

4. The fluorescence detector of claim 1, wherein a number of the at least one irradiating module is two or more, and the two or more irradiating modules are disposed in parallel along one direction, and
wherein respective excitation light selecting units of the two or more irradiating modules convert respective lights emitted from respective at least one light source into respective excitation lights having different wavelengths.

5. The fluorescence detector of claim 1, wherein the at least one light source comprises at least one light-emitting diode (LED) lighting.

6. The fluorescence detector of claim 5, wherein a number of the at least LED lighting is equal to a number of the at least one sample unit.

7. The fluorescence detector of claim 1, wherein the fluorescence selecting unit comprises an emission filter.

8. The fluorescence detector of claim 7, wherein the emission filter is formed of a plurality of the emission filters, and the plurality of emission filters are changeable with respect to one another.

9. The fluorescence detector of claim 1, wherein the light-receiving unit comprises a charge-coupled device (CCD) camera.

10. The fluorescence detector of claim 1, wherein the beamsplitter comprises a dichroic filter.

11. The fluorescence detector of claim 10, wherein an incident angle of the excitation light that is incident on the dichroic filter is between 40 degrees and 50 degrees.

12. The fluorescence detector of claim 1, wherein the excitation light selecting unit comprises an excitation filter which outputs a light having a selected wavelength.

13. The fluorescence detector of claim 12, wherein an incident angle of light from the irradiating module that is incident on the excitation filter is between −5 degrees and 5 degrees.

14. The fluorescence detector of claim 1, wherein the excitation light is a selected wavelength light.

15. The fluorescence detector of claim 1, wherein the irradiating module further comprises a wave guide which is disposed between the at least one light source and the excitation light selecting unit and divides the light emitted from the at least one light source into a plurality of lights that are parallel to one another.

16. The fluorescence detector of claim 15, wherein the wave guide is a glass wave guide which is integrally formed of a glass material.

17. The fluorescence detector of claim 15, wherein the wave guide comprises a plurality of optical fibers, and
side ends of the plurality of optical fibers toward the at least one light source contact one another, and side ends of the plurality of optical fibers toward the excitation light selecting unit are separate from one another.

18. A fluorescence detector for detecting fluorescence emitted from at least one sample contained in at least one sample unit, the fluorescence detector comprising:
an irradiating module which irradiates an excitation light to the sample;
a fluorescence selecting unit which selectively transmits fluorescence emitted from the sample;
a light-receiving unit which detects the fluorescence; and
a telecentric lens positioned between the fluorescence selecting unit and the light-receiving unit,
wherein the irradiating module comprises:
a light source comprising at least one laser diode which emits a light; and
a beamsplitter which controls the light emitted from the at least one laser diode of the light source to travel to the sample, and transmits the fluorescence emitted from the sample.

19. The fluorescence detector of claim 18, wherein a wavelength of the light emitted from the at least one laser diode is materially the same as a wavelength of light capable of exciting a fluorescent material comprised in the sample.

20. The fluorescence detector of claim 18, wherein the irradiating module further comprises an excitation light selecting unit which is disposed between the light source and the beamsplitter and converts the light emitted from the light source into the excitation light.
